(19) United States
(12) Patent Application Publication
(10) Pub. No.: US 2010/0038767 A1
(43) Pub. Date: Feb. 18, 2010

(54) SEMICONDUCTOR DEVICE AND METHOD OF MANUFACTURING THE SAME

(75) Inventors: Hiroshi MORIYA, Ibaraki (JP); Hisashi TANIE, Ibaraki (JP); Emi SAWAYAMA, Tokyo (JP); Masahiro YAMAGUCHI, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/538,390

(22) Filed: Aug. 10, 2009

(30) Foreign Application Priority Data
Aug. 18, 2008 (JP) 2008-209452

(51) Int. Cl. H01L 25/11; H01L 21/50

(52) U.S. Cl. 257/686; 438/107; 257/E25.027; 257/E21.499

(57) ABSTRACT

The semiconductor device includes a stacked semiconductor package in which end portions of a plurality of flexible substrates have bonded portions which are connected together by wirings and in which a plurality of semiconductor packages are electrically connected to a mother substrate via the bonded portions. In at least a part of a region of portions of the plurality of flexible substrates that extends from the side surfaces of each of the semiconductor elements, and that is present between side surfaces of each of the semiconductor elements and the bonded portions of the flexible substrates, the plurality of flexible substrates have a curved portion, and the shape of the curved portion of at least one flexible substrate is different from the shape of a curved portion of another flexible substrate adjacent to this flexible substrate.

### BACKGROUND OF THE INVENTION

1. Field of the Invention

The present invention relates to a semiconductor device and a method of manufacturing the semiconductor device.

2. Description of the Related Art

Semiconductor devices are used in various kinds of information equipment, such as large computers, personal computers and mobile devices, and the number of required functions and required storage capacity is increasing year by year. As a result of such high performance designs and large capacity designs, the area of packaging semiconductor elements on a base substrate has increased, providing a factor that is responsible for impeding miniaturization.

Therefore, there have been developed mounting techniques for stacking a plurality of semiconductor elements on a base substrate as methods of mounting a large number of semiconductor elements within the limited area of the base substrate.

As such semiconductor stacking techniques, there are methods which involve stacking on a base substrate a plurality of flexible substrates on which semiconductor elements are mounted and depressing the flexible substrates by use of a heating tool or an ultrasonic tool, thereby bonding the flexible substrates together or bonding the base substrate and the flexible substrates together. As such methods of stacking, a method using a heating tool is disclosed in Japanese Patent Laid-Open No. 2002-57279 and a method using an ultrasonic tool is disclosed in Japanese Patent Laid-Open No. 2006-310523.

Japanese Patent Laid-Open No. 2002-57279 discloses a stacked semiconductor device in which a plurality of wiring substrates can be fixed by soldering on a base substrate without heating the wiring substrates in a reflow furnace. This semiconductor device is provided with a semiconductor chip which is flexible and in which an internal electrode is provided, a wiring substrate which is flexible and which is provided with a wiring pattern electrically connected to the internal electrode of the semiconductor chip, and an external electrode which is electrically connected to this wiring pattern and which is provided in an end portion of the wiring substrate.

In order to connect circuit substrates efficiently, with high accuracy and with high reliability, Japanese Patent Laid-Open No. 2006-310523 discloses a semiconductor device which is provided with a first interposer and a second interposer both of which have an internal terminal on one surface, and which is provided with a semiconductor chip disposed between the first interposer and the second interposer. In this semiconductor device, the back surface of the semiconductor chip is fixed to one surface of the first interposer and the front surface of the semiconductor chip is fixed to one surface of the second interposer. The internal terminal provided on one surface of the first interposer and the internal terminal provided on one surface of the second interposer are bonded together.

Furthermore, Japanese Patent Laid-Open No. 8-70079 discloses a high-reliability and low-cost ultrathin semiconductor device which permits repairs during mounting. For the purpose of providing a highly functional semiconductor module with the same volume by obtaining a stacked structure by use of a plurality of these ultrathin semiconductors, in a semiconductor device obtained by metallurgically directly connecting a metal lead frame and an electrode on an LSI chip, a lead frame the whole of which is made uniformly thin is used, and the peripheries of the lead frame and the chip are resin-molded.

The present inventors have recognized the following problem That is, as described in Japanese Patent Laid-Open No. 2002-57279, Japanese Patent Laid-Open No. 2006-310523 and Japanese Patent Laid-Open No. 8-70079, in a method which involves depressing flexible substrates by the use of a tool, thereby bonding the flexible substrates together or by bonding a base substrate and the flexible substrates together, tension is generated in the flexible substrates during the depressing that is performed by use of the tool. This tension generated in the flexible substrates remains even after the flexible substrates are bonded together. As well, excessive tensile stress may sometimes be generated by this tension in bonded portions of the flexible substrates. Because this tensile stress works on the bonded portions so as to tear off the flexible substrates, fracture of the bonded portions is feared.

Furthermore, even when the bonding of the flexible substrates is thoroughly performed, immediately after the bonding of the flexible substrates performed by use of a tool, thermal stress is generated due to a difference in the coefficient of linear expansion of each member when the flexible substrates are subjected to temperature cycles in a succeeding step. The addition of this thermal stress to the above-described tensile stress increases the fear that the bonded portions of the flexible substrates may fracture.

### SUMMARY

The present invention has been made to solve the above-described problem.

According to an aspect of a semiconductor device of the present invention, the semiconductor device comprises: a plurality of semiconductor packages having a semiconductor element and a flexible substrate in which the semiconductor element is provided with an overlap and is electrically connected, an end portion of the flexible substrate that extends from side surfaces of the semiconductor element, and that has wirings on both surfaces; and a mother substrate on a front surface of which the plurality of semiconductor packages are stacked. The semiconductor device includes the stacked semiconductor package in which the end portions of the plurality of flexible substrates have bonded portions which are bonded together by the wirings and the plurality of semiconductor packages are electrically connected to the mother substrate via the bonded portions. In this semiconductor device, in at least a part of a portion where regions of the plurality of flexible substrates are present between the side surfaces of each of the semiconductor elements and the bonded portions of the flexible substrates, and in which the plurality of flexible substrates extend from the side surfaces of each of the semiconductor elements, the plurality of flexible substrates have a curved portion, and the shape of the curved portion of at least one of the flexible substrates is different from the shape of a curved portion of another flexible substrate adjacent to the flexible substrate.

As described above, in the semiconductor device of the present invention, the shape of the curved portion of at least one flexible substrate is different from the shape of the curved portion of another flexible substrate adjacent to this flexible substrate. That is, the end portions of at least one flexible substrate are bonded to the bonded portions, with a part of a region between the side surfaces of the semiconductor element and the bonded portions kept in a loose condition.

Therefore, according to the present invention, by suppressing the tension generated in flexible substrates, it is possible to reduce the stress that acts on the bonded portions of the flexible substrates and to improve the reliability of the bonded portions.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a sectional view showing the essential part of a semiconductor device of a first embodiment;

FIG. 1B is a plan view showing the semiconductor device of the first embodiment;

FIG. 2A is a plan view showing a semiconductor module on which a semiconductor package of the first embodiment is mounted;

FIG. 2B is a side view showing a semiconductor module on which the semiconductor package of the first embodiment is mounted;

FIG. 3A is a sectional view showing the semiconductor package of the first embodiment;

FIG. 3B is a plan view showing the semiconductor package of the first embodiment;

FIG. 4A is a sectional view showing the manufacturing process of the semiconductor device of the first embodiment;

FIG. 4B is a sectional view showing the manufacturing process of the semiconductor device of the first embodiment;

FIG. 4C is a sectional view showing the manufacturing process of the semiconductor device of the first embodiment;

FIG. 4D is a sectional view showing the manufacturing process of the semiconductor device of the first embodiment;

FIG. 4E is a sectional view showing the manufacturing process of the semiconductor device of the first embodiment;

FIG. 4F is a sectional view showing the manufacturing process of the semiconductor device of the first embodiment;

FIG. 5A is a sectional view showing the manufacturing process of a semiconductor device of a second embodiment;

FIG. 5B is a sectional view showing the manufacturing process of the semiconductor device of the second embodiment;

FIG. 5C is a sectional view showing the manufacturing process of the semiconductor device of the second embodiment;

FIG. 5D is a sectional view showing the manufacturing process of the semiconductor device of the second embodiment;

FIG. 5E is a sectional view showing the manufacturing process of the semiconductor device of the second embodiment;

FIG. 5F is a sectional view showing the manufacturing process of the semiconductor device of the second embodiment;

FIG. 6 is a plan view showing the semiconductor device of the second embodiment shown in FIG. 5D;

FIG. 7A is diagram showing stress distribution at a bonding interface of a flexible substrate in a stacked semiconductor package of the first embodiment;

FIG. 7B is a sectional view showing the essential part of a semiconductor device to indicate the direction of distance x in FIG. 7A;

FIG. 8 is a sectional view showing the essential part of a semiconductor device of a third embodiment;

FIG. 9 is a plan view showing a spacer of the semiconductor device of the third embodiment;

FIG. 10 is a plan view showing a spacer of a semiconductor device of a fourth embodiment; and

FIG. 11 is a sectional view showing the essential part of a semiconductor device of a fifth embodiment.

### DETAILED DESCRIPTION OF THE PREFERRED EMBODIMENTS

The present invention relates to a semiconductor device and a method of manufacturing the semiconductor device and, more particularly, to a method of manufacturing a semiconductor device having a step of bonding a plurality of flexible substrates by depressing the plurality of flexible substrates by use of a tool.

In an aspect of the method of manufacturing a semiconductor device of the present invention, there is provided a method of manufacturing a semiconductor device intended for a semiconductor device having: a plurality of semiconductor packages each having a semiconductor element and a flexible substrate in which the semiconductor element is provided with an overlap and is electrically connected, an end portion of the flexible substrate that extends from side surfaces of the semiconductor element, and that has wirings on both surfaces; and a mother substrate on a front surface of which the plurality of semiconductor packages are stacked, in which the semiconductor device includes a stacked semiconductor package in which the end portions of the plurality of flexible substrates have bonded portions which are bonded together by the wirings, and the plurality of semiconductor packages are electrically connected to the mother substrate via the bonded portions. This method of manufacturing a semiconductor device having: a first step of disposing the plurality of semiconductor packages and a spacer for spacing the semiconductor element or the flexible substrate from the mother substrate by stacking them on the front surface of the mother substrate; a second step of forming the bonded portions by depressing the end portions of the plurality of flexible substrates; a third step of removing the spacer from the stacked semiconductor package; and a fourth step of bringing the plurality of semiconductor packages into intimate contact with the mother substrate by depressing the semiconductor elements of the semiconductor packages stacked on the mother substrate.

To manufacture the above-described semiconductor device, in another aspect of the method of manufacturing a semiconductor device of the present invention, there is provided a method of manufacturing a semiconductor device intended for a semiconductor device having: a first step of disposing the plurality of semiconductor packages and a spacer for spacing the semiconductor element or the flexible substrate from the mother substrate by stacking them on the front surface of the mother substrate; a second step of forming the bonded portions by depressing the end portions of the plurality of flexible substrates; and a third step of deforming the spacer by depressing the semiconductor elements or flexible substrates of the semiconductor packages stacked on the mother substrate.

The method of manufacturing a semiconductor device of the present invention can be otherwise expressed as below.

The method of manufacturing a semiconductor device of the present invention has a first step of stacking a first flexible substrate on which a first semiconductor element is mounted and a second flexible substrate on which a second semiconductor element is mounted, and a second step of bonding together a first wiring group provided on the first flexible substrate, and a second wiring group that is provided on the second flexible substrate and that is electrically connected to the second semiconductor element by depressing the wiring groups by use of a tool. This method of manufacturing a semiconductor device has a step of reducing the tension of the flexible substrates which is generated due to the second step of bonding by depressing through the use of a tool.

The method of manufacturing a semiconductor device of the present invention has a first step of stacking a first flexible substrate on which a first semiconductor element is mounted, a spacer, and a second flexible substrate on which a second semiconductor element is mounted, a second step of bonding together a first wiring group provided on the first flexible substrate, and a second wiring group provided that is on the second flexible substrate and that is electrically connected to the second semiconductor element by performing depressing through the use of a tool, and a step of narrowing a gap between the first semiconductor element and the second semiconductor element by removing the spacer, which is performed after the second step.

The method of manufacturing a semiconductor device of the present invention has a first step of stacking a first flexible substrate on which a first semiconductor element is mounted and a second flexible substrate on which a second semiconductor element is mounted, and providing a supporting member which supports the second flexible substrate, a second step of bonding together a first wiring group provided on the first flexible substrate, and a second wiring group that is provided on the second flexible substrate and electrically that is connected to the second semiconductor element by depressing the wiring groups through the use of a tool, and a step of suppressing the tension of the flexible substrates, which is generated due to the second step of bonding by depressing through the by use of a tool, by removing the supporting member, which is performed after the second step.

In an aspect of the semiconductor device of the present invention, the semiconductor device is provided with a plurality of semiconductor packages each having a semiconductor element and a flexible substrate in which the semiconductor element is provided with an overlap and is electrically connected, an end portion of the flexible substrate that extends from side surfaces of the semiconductor element, and that has wirings on both surfaces; and a mother substrate on a front surface of which the plurality of semiconductor packages are stacked. The semiconductor device includes a stacked semiconductor package in which the end portions of the plurality of flexible substrates have bonded portions which are bonded together by the wirings, and the plurality of semiconductor packages are electrically connected to the mother substrate via the bonded portions. In at least a part of a portion where regions of the plurality of flexible substrates are present between the side surfaces of each of the semiconductor elements and the bonded portions of the flexible substrates, and in which the plurality of flexible substrates extend from the side surfaces of each of the semiconductor elements, the plurality of flexible substrates have a curved portion, and the shape of the curved portion of at least one of the flexible substrates is different from the shape of a curved portion of another flexible substrate adjacent to the flexible substrate.

In another aspect of the semiconductor device of the present invention, the semiconductor device is provided with a plurality of semiconductor packages each having a plate-like semiconductor element and a flexible substrate in which the semiconductor element is provided with an overlap and is electrically connected, end portions of the flexible substrate that extend from side surfaces of each of the semiconductor elements, and that has wirings on both surfaces; and a mother substrate on a front surface of which the plurality of semiconductor packages are stacked. The semiconductor device includes a stacked semiconductor package in which the end portions of the plurality of flexible substrates have bonded portions which are bonded together by the wirings, and the plurality of semiconductor packages are electrically connected to the mother substrate via the bonded portions. Both end portions of at least one of the flexible substrates are bonded to the bonded portions, with a region between the side surfaces of the semiconductor elements and the bonded portions kept in a loose condition.

The semiconductor device of the present invention is further provided with a resin member which reduces the stress generated in the bonded portions of the flexible substrates, and which is provided between the semiconductor package and the mother substrate or two adjacent semiconductor packages. By arranging this resin member, it is possible that the shape of the curved portion of at least one flexible substrate and the shape of a curved portion of another flexible substrate adjacent to this flexible substrate are different from each other.

In the semiconductor device of the present invention, the resin member is provided in a part of a region present between the semiconductor package and the mother substrate or a part of a region present between two adjacent semiconductor packages.

As described above, according to the present invention, in a method of manufacturing a semiconductor device having a step of bonding together a plurality of flexible substrates on each of which a semiconductor element is mounted by depressing the plurality of flexible substrates by use of a tool, the method of manufacturing a semiconductor device has a step of suppressing the tension generated in the flexible substrates by depressing the plurality of flexible substrates by use of a tool. As a result of this, the stress generated in the bonded portions of the flexible substrates is reduced and this enables the reliability of the bonded portions to be improved.

Hereinafter, embodiments of the present invention will be described with reference to the drawings.

### First Embodiment

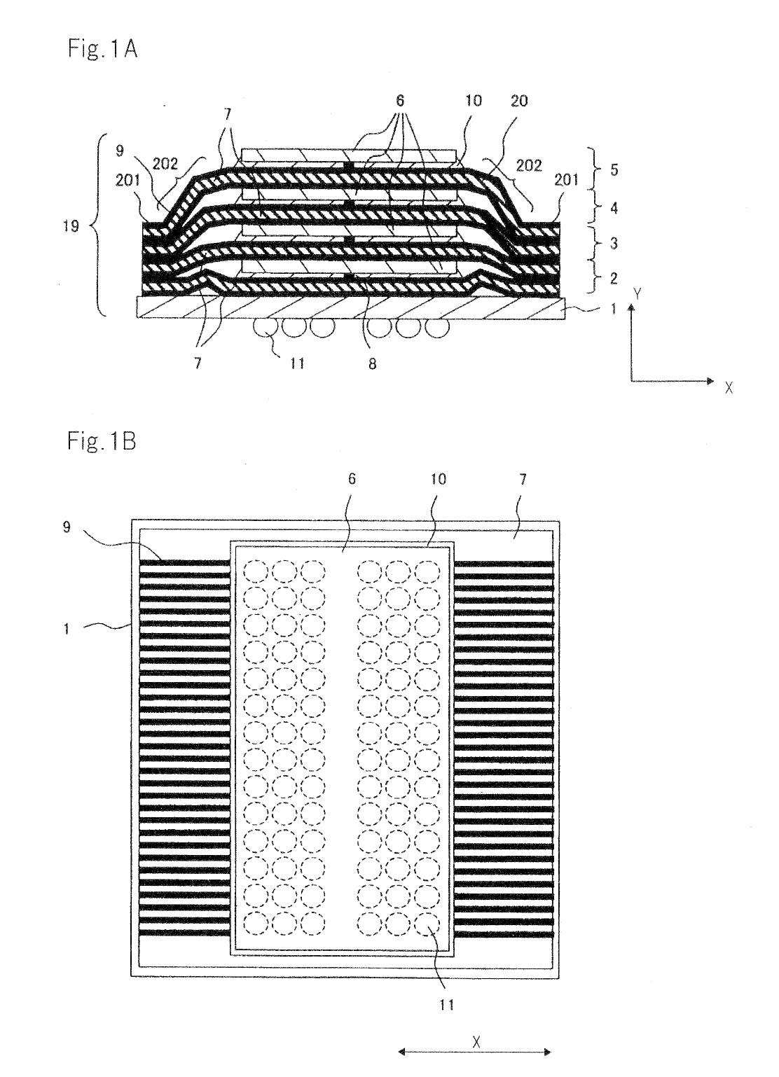

FIG. 1A shows a sectional view of the essential part of a semiconductor device of the first embodiment. FIG. 1B shows a plan view of the semiconductor device of the first embodiment.

The semiconductor device shown in these figures is configured in such a manner that four semiconductor packages 2 to 5, i.e., the first to fourth semiconductor packages are stacked on mother substrate 1. Each of first to fourth semiconductor packages 2 to 5 includes semiconductor element 6 and flexible substrate 7.

As shown in FIG. 1A, semiconductor element 6 is provided on a front surface of flexible substrate 7, and bump 8 provided on a front surface of semiconductor element 6 and wirings 9 of flexible substrate 7 are bonded together, whereby semiconductor element 6 and flexible substrate 7 are electrically connected together. Encapsulant resin 10 is provided between a back surface of semiconductor element 6 and the front surface of flexible substrate 7, and a bonded portion between bump 8 of semiconductor element 6 and wirings 9 is protected by this encapsulant resin 10.

In this embodiment, silicon having a thickness in the order of 0.1 mm is used as semiconductor element 6, polyimide resin 20 having a thickness in the order of 0.025 mm is used as flexible substrate 7, and copper having a thickness in the order of 0.01 mm is used as wirings 9 provided on the front surface of flexible substrate 7.

Incidentally, a coating consisting of nickel and the like is applied to a surface of wirings 9 thereby to protect the surface, and surfaces of areas where it is necessary to insulate wirings 9 are covered with a thin resin film. Wirings 9 provided on both surfaces of flexible substrate 7 are electrically connected with each other via a plurality of through-vias (not shown) provided in polyimide 20. A glass epoxy substrate having two-layer wirings is used as mother substrate 1.

First semiconductor package 2 disposed at the lowest level of first to fourth semiconductor packages 2 to 5, which are stacked, is electrically connected to mother substrate 1, because terminals disposed in a row on mother substrate 1 and some of wirings 9 are bonded together. Above the bonded portions between mother substrate 1 and first semiconductor package 2, wirings 9 of first semiconductor package 2 and wirings 9 of second semiconductor package 3, which is disposed in a position one level higher than first semiconductor package 2, are bonded together. As a result of this, second semiconductor package 3 is electrically connected to mother substrate 1 via first semiconductor package 2 positioned at a level lower than second semiconductor package 3.

Similarly, above the bonded portions between mother substrate 1 and first semiconductor package 2, wirings 9 of second semiconductor package 3 and wirings 9 of third semiconductor package 4, which is disposed in a position one level higher than second semiconductor package 3, are bonded together. As a result of this, third semiconductor package 4 is electrically connected to mother substrate 1 via first and second semiconductor packages 2, 3 positioned at levels lower than third semiconductor package 4.

Also, above the bonded portions between mother substrate 1 and first semiconductor package 2, wirings 9 of third semiconductor package 4 and wirings 9 of fourth semiconductor package 5, which is disposed in a position one level higher than third semiconductor package 4, are bonded together. As a result of this, fourth semiconductor package 5 is electrically connected to mother substrate 1 via first to third semiconductor packages 2 to 4 positioned at levels lower than fourth semiconductor package 5. The portion where the plurality of flexible substrates 7 are stacked and are each bonded to mother substrate 1 is called bonded portion 201 of flexible substrates 7.

Solder balls 11 are provided on the surface of mother substrate 1 opposite to the surface where first to fourth semiconductor packages 2 to 4 are disposed. The structure in which mother substrate 1 and the plurality of semiconductor packages 2 to 5 are stacked is called stacked semiconductor package 19.

Each of flexible substrates 7 is bending-deformed in order to compensate for differences in the height of the bonding position of semiconductor packages 2 to 5. Furthermore, at least flexible substrate 7 of fourth semiconductor package 5, which is positioned at the highest level, is bending-deformed so as to reduce the tension generated during the bonding of flexible substrate 7. As a result of this, the tensile stress generated in bonded portion 201 between flexible substrate 7 of fourth semiconductor package 5 and flexible substrate 7 of third semiconductor package 4 is reduced and the reliability of above-described bonded portion 201 is improved.

That is, as shown in the sectional view of FIG. 1A, in the end portions of the plurality of flexible substrates 7, which are extended to the outside a region where semiconductor elements 6 and flexible substrates 7 overlap each other, flexible substrates 7 have curved portions 202 in at least a part of the region between the side surfaces of semiconductor elements 6 and bonded portions 201 of flexible substrates 7. Regarding the sectional shape of curved portions 202, the shapes of curved portions 202 of flexible substrates 7 which are adjacent to each other are different from each other.

In other words, the curvature of curved portion 202 of flexible substrate 7 which intersects any normal line on the front surface of mother substrate 1 and the curvature of curved portion 202 of another flexible substrate 7 adjacent to this flexible substrate 7 in a position where the curved portion intersects the normal line of curved portion 202 are different from each other in at least a part of a region between the side surfaces of semiconductor elements 6 and bonded portions 201 of flexible substrates 7.

It can also be otherwise said that the inclination of the front surfaces of curved portions 202 is positive (plus) with respect to the direction of X-axis, for curved portions 202 of flexible substrates 7 in at least a part of a region, as shown in FIG. 1A, at a position between the side surfaces of semiconductor elements 6 and bonded portions 201 of flexible substrates 7, on a section formed by an direction of X-axis, which is parallel to the front surface of the mother substrate and which is the direction that is headed away from semiconductor elements 6 to bonded portions 201, and formed by a direction of Y-axis, which is a normal direction of the front surface of mother substrate 1. This means that in FIG. 1A, a part of curved portion 202 of flexible substrate 7 of first semiconductor package 2 disposed at the lowest level, i.e., the portion of curved portions 202 on semiconductor element 6 side, bulges upward with respect to the direction of Y-axis.

Furthermore, it can also be otherwise said that the front surfaces of curved portions 202 have an apex with respect to the direction of X-axis of FIG. 1A, for curved portions 202 of flexible substrates 7 in at least a part of a region, at a position between the side surfaces of semiconductor elements 6 and bonded portions 201 of flexible substrates 7, on a section formed by the directions of the X-axis and Y-axis. This means that in FIG. 1A, a part of curved portion 202 of flexible substrate 7 of first semiconductor package 2 disposed at the lowest level, i.e., the portion of curved portions 202 on semiconductor element 6 side, drops toward bonded portion 201 from a position where curved portions 202 bulge upward with respect to the direction of Y-axis.

Incidentally, a structure in which a plurality of semiconductor packages 2 to 5 are stacked, disposed on the front surface of mother substrate 1, and which are electrically connected to mother substrate 1 via bonded portions 201 of flexible substrates 7, is called stacked semiconductor package 19.

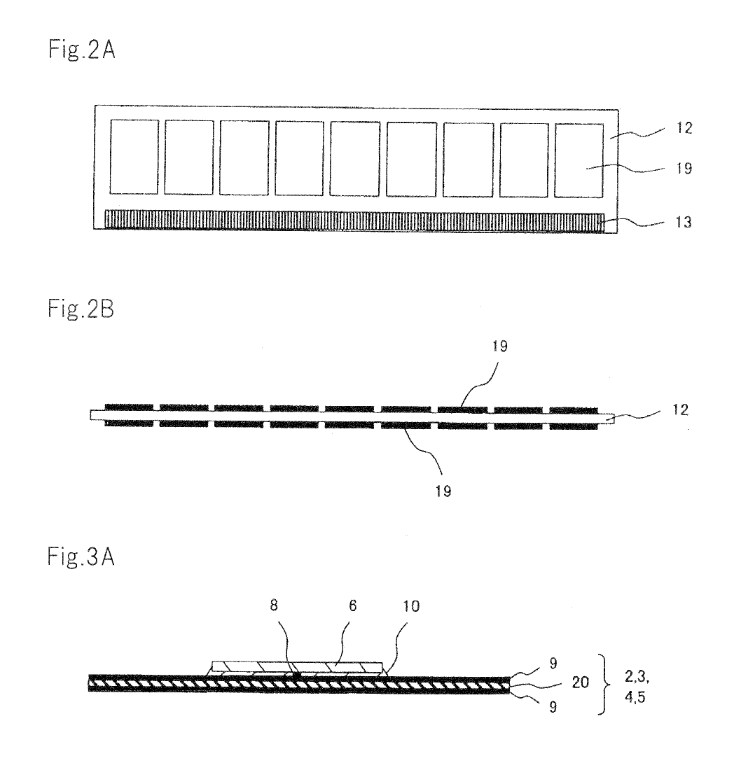

FIGS. 2A and 2B show an example of a semiconductor module on which stacked semiconductor package 19 manufactured according to the method of manufacturing a semiconductor device of the first embodiment is mounted. The semiconductor module is configured by mounting a plurality of stacked semiconductor packages 19 on printed circuit board 12 on which wiring patterns (not shown) are formed. External connection terminal 13 is formed on printed circuit board 12.

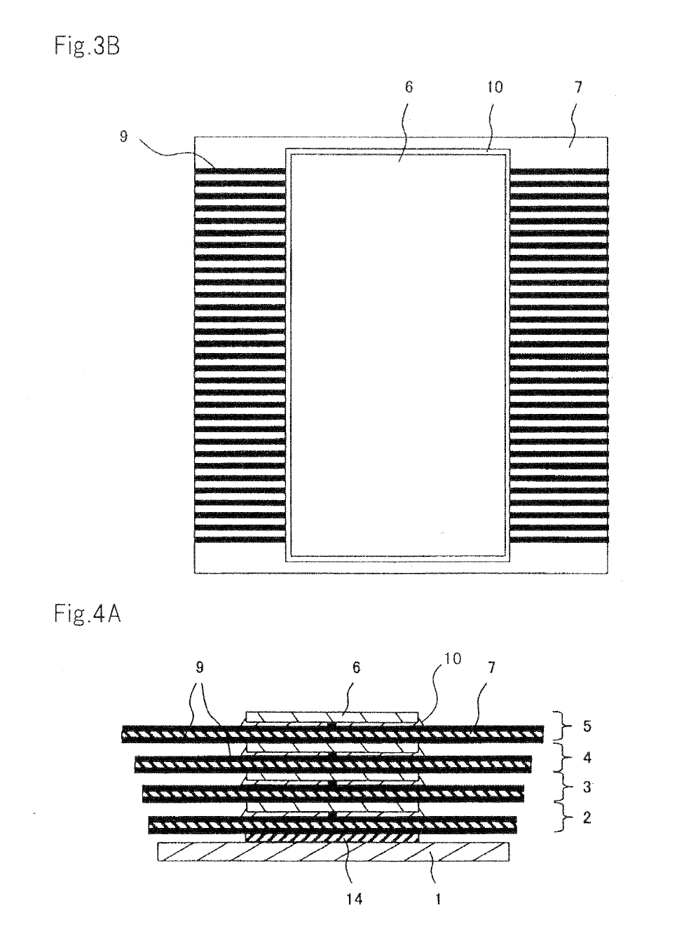

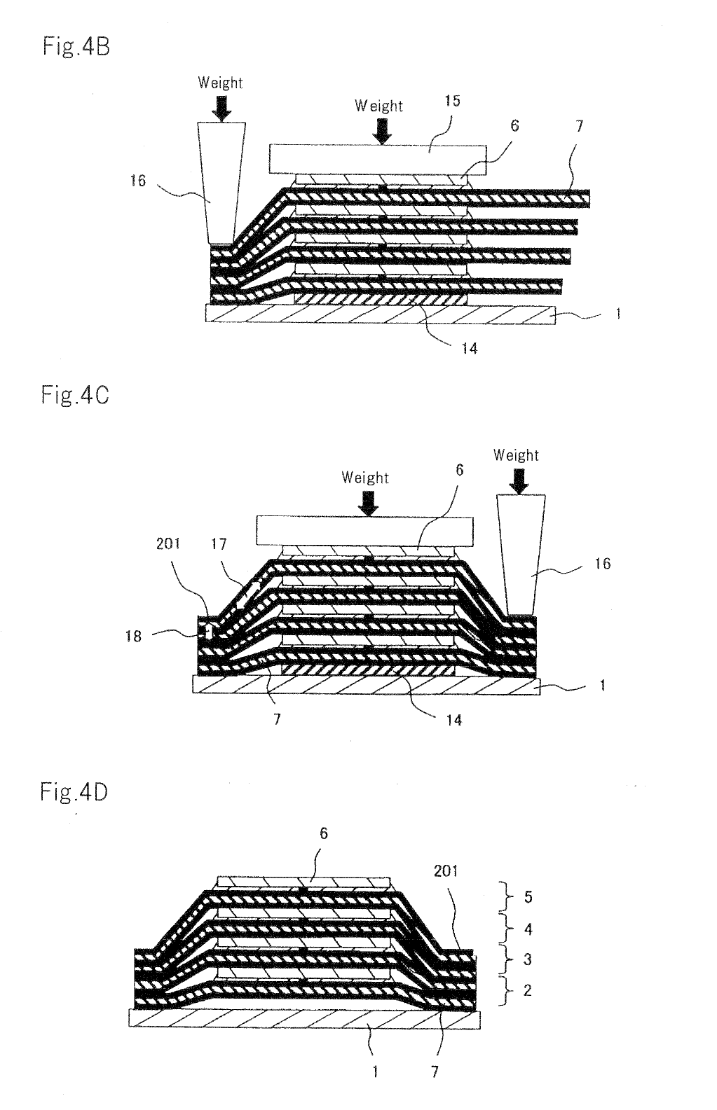

The manufacturing process of the semiconductor device of the first embodiment is shown in FIGS. 3A and 3B and FIGS. 4A to 4F. A step of fabricating semiconductor package 6 which is subjected to bending deformation for reducing the tension of flexible substrate 7 is shown.

(1) First, as shown in FIGS. 3A and 3B, semiconductor element 6 is provided on flexible substrate 7, and a plurality of semiconductor packages 2 to 5 are fabricated. Bump 8 provided on the front surface of semiconductor element 6 and wirings 9 are bonded together, whereby semiconductor element 6 and wirings 9 of flexible substrate 7 are electrically connected. By providing encapsulant resin 10 between the back surface of semiconductor element 6 and the front surface of flexible substrate 7, a bonded portion between bump 8 of semiconductor element 6 and wirings 9 is protected.

(2) Next, as shown in FIG. 4A, spacer 14 and semiconductor packages 2 to 5 are stacked on mother substrate 1 in this order. Spacer 14 is a PTFE sheet (polytetrafluoroethylene sheet) having a thickness, for example, in the order of 0.3 mm.

(3) Next, a load is applied to an upper part of semiconductor element 6 positioned at the highest level via jig 15 made from, for example, a stainless steel plate, whereby semiconductor packages 2 to 5, spacer 14 and mother substrate 1 are fixed. Subsequently, the end portions of a plurality of flexible substrates 7 on one side extending horizontally from semiconductor elements 6 are depressed as a whole by use of tool 16, whereby one end of each of flexible substrates 7 is bent At this time, a load is applied to the plurality of flexible substrates 7 by use of tool 16 from above one end portion of flexible substrate 7 positioned at the highest level, whereby one end portion of each of flexible substrates 7 is bending-deformed while flexible substrates 7 which are adjacent to each other are being brought into contact with each other. As a result, wirings 9 of stacked semiconductor packages 2 to 5 and mother substrate 1 are bonded together.

(4) Subsequently, as shown in FIG. 4C, the end portions of the plurality of flexible substrates 7 on the other side extending horizontally from semiconductor elements 6 are depressed as a whole by use of tool 16, whereby the other end portions of each of flexible substrates 7 are bent and wirings 9 of first to fourth semiconductor packages 2 to 5 and mother substrate 1 are bonded together.

In this embodiment, as shown in FIGS. 4B and 4C, bonded portion 201 is formed by depressing both end portions of flexible substrates 7 by use of tool 16 only one side at a time. The method of bonding is not limited to this, but both end portions of flexible substrates 7 may be bonded together by a one bonding step. In a bonding step which involves using tool 16, it is possible to perform the bonding of wirings with good efficiency by using a heating tool or an ultrasonic tool.

As a result of the bending deformation of flexible substrates 7 by use of tool 16, tension 17 is generated in flexible substrates 7. Due to tension 17, tensile stress 18 is generated in bonded portion 201 between flexible substrates 7 and in bonded portion 20 between mother substrate 1 and flexible substrate 7. The magnitude of tension 17 is the largest in flexible substrate 7 of fourth semiconductor package 5 positioned at the highest level This is because the amount of deformation caused by the bending of flexible substrate 7 of fourth semiconductor package 5 positioned at the highest level is the largest That is, the largest tensile stress is generated at the bonding interface between flexible substrate 7 positioned at the highest level and flexible substrate 7 positioned immediately thereunder. If this tensile stress is excessive, the bonding interface between flexible substrates 7 may be fractured. For this reason, it is necessary to minimize the tensile stress generated at the bonding interface by reducing the above-described tension 17, thereby increasing the reliability of the bonded portion.

(5) Next, as shown in FIG. 4D, spacer 14 is removed from between flexible substrate 7 positioned at the lowest level and mother substrate 1. Because clearance is obtained by the space from which spacer 14 is removed, tension 17 generated in flexible substrates 7 decreases.

(6) Next, as shown in FIG. 4E, a load is applied in a direction vertical to the front surface of mother substrate 1 by use of tool 15 formed from, for example, a stainless steel plate from above semiconductor elements 6 positioned at the highest level, whereby semiconductor elements 6 are pushed against mother substrate 1. At this time, each of flexible substrates 7 is deformed and tension 17 decreases further. As a result of this, the stress generated in bonded portion 201 of flexible substrates 7 is reduced and it is possible to improve the reliability of bonded portion 201.

(7) Last, as shown in FIG. 4F, solder balls 11 are provided on a surface of mother substrate 1 opposite to the surface where first to fourth semiconductor packages 2 to 5 are disposed.

### Second Embodiment

Next, another embodiment is shown as a method of reducing the stress generated in bonded portions 201 of flexible substrates 7 by reducing the tension of flexible substrates 7.

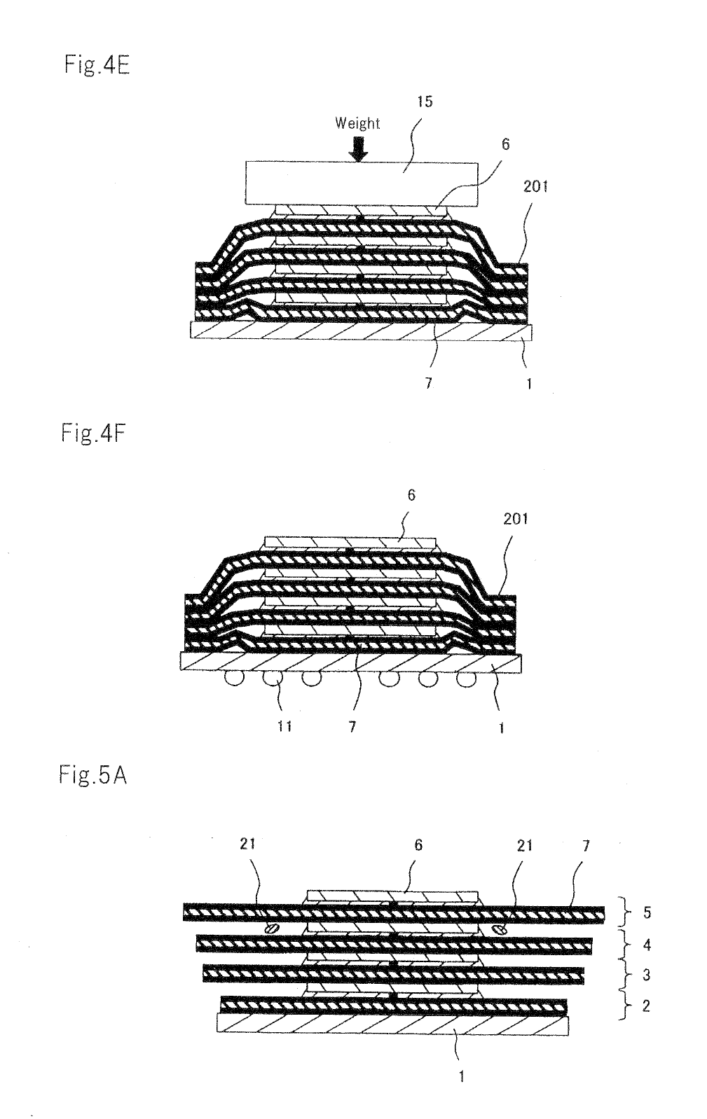

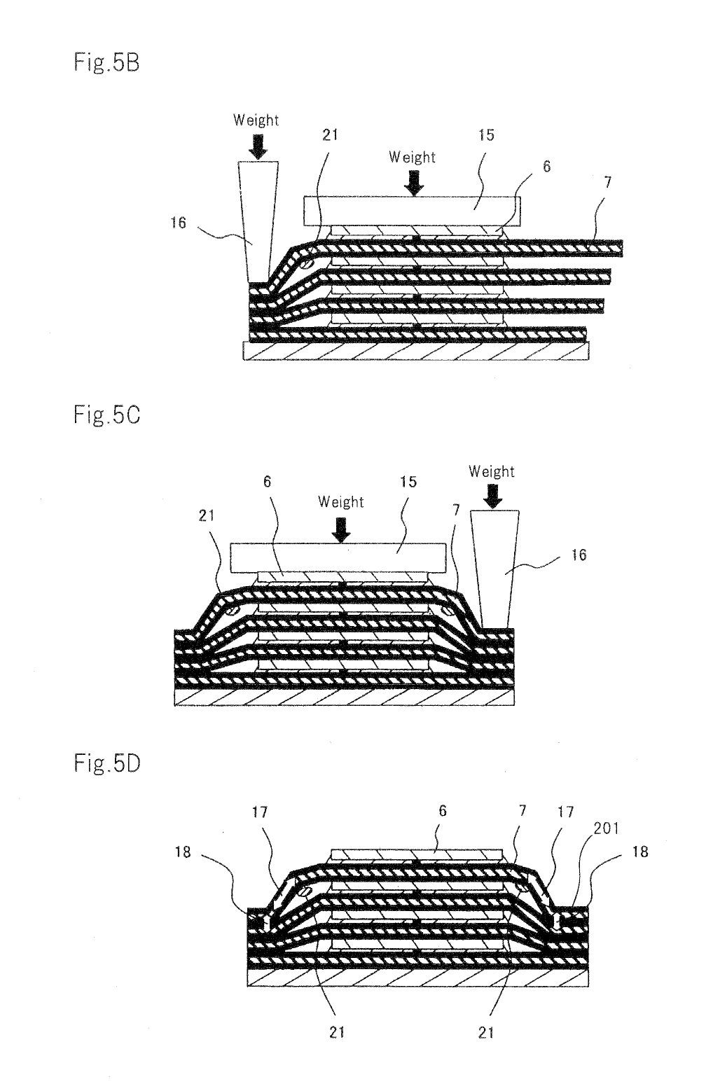

FIGS. 5A to 5F show the manufacturing process of a semiconductor device of the second embodiment. A step of fabricating a stacked semiconductor package which involves bending deformation for reducing the tension of flexible substrates 7 is shown. FIG. 6 shows a plan view of FIG. 5D.

(1) First, in the same manner as in the first embodiment, as shown in FIG. 3A, semiconductor element 6 is provided on flexible substrate 7, and first to fourth semiconductor packages 2 to 5 are fabricated.

(2) Next, semiconductor packages 2 to 5 are disposed by stacking on mother substrate 1. Subsequently, as shown in FIG. 5A, longitudinal members 21 that function as a pair of spacers are inserted at least in the vicinity where both side surfaces of semiconductor element 6 are opposite each, semiconductor element 6 being below flexible substrate 7 of fourth semiconductor package 5 positioned at the highest level. Needle members made of, for example, metal may be used as longitudinal members 21.

(3) Next, a load is applied to an upper portion of semiconductor element 6 positioned at the highest level by use of jig 15 fabricated from, for example, a stainless steel plate, whereby semiconductor packages 2 to 5 and mother substrate 1 are fixed. Subsequently, the end portions of a plurality of flexible substrates 7 on one side extending horizontally from semiconductor elements 6 are depressed as a whole by use of tool 16, whereby one end of each of flexible substrates 7 is bent. At this time, longitudinal members 21 are fixed so that long members 21 become supporting parts during the bending of the end portions of flexible substrates 7. As shown in FIG. 5B, a load is applied to the plurality of flexible substrates 7 by use of tool 16 from above one end portion of flexible substrate 7 positioned at the highest level, whereby one end portion of each of flexible substrates 7 is bending-deformed while flexible substrates 7 which are adjacent to each other are being brought into contact with each other.

As a result, wirings 9 of stacked semiconductor packages 2 to 5 and mother substrate 1 are bonded together. Above the bonded portions between mother substrate 1 and first semiconductor package 2, wirings 9 of first semiconductor package 2 and wirings 9 of second semiconductor package 3, which is disposed in a position one level higher than first semiconductor package 2, are bonded together, whereby second semiconductor package 3 is electrically connected to mother substrate 1 via first semiconductor package 2 positioned at a level lower than second semiconductor package 3.

Similarly, above the bonded portions between mother substrate 1 and first semiconductor package 2, wirings 9 of second semiconductor package 3 and wirings 9 of third semiconductor package 4, which is disposed in a position one level higher than second semiconductor package 3, are bonded together, whereby third semiconductor package 4 is electrically connected to mother substrate 1 via first and second semiconductor packages 2, 3 positioned at levels lower than third semiconductor package 4. Also, similarly, above the bonded portions between mother substrate 1 and first semiconductor package 2, wirings 9 of third semiconductor package 4 and wirings 9 of fourth semiconductor package 5, which is disposed in a position one level higher than third semiconductor package 4, are bonded together, whereby fourth semiconductor package 5 is electrically connected to mother substrate 1 via first to third semiconductor packages 2 to 4 positioned at levels lower than fourth semiconductor package 5. In the bonding performed using tool 16, it is possible to perform the bonding of wirings 9 with good efficiency by using a heating tool or an ultrasonic tool.

(4) Next, as shown in FIG. 5C, end portions of the plurality of flexible substrates 7 on the other side extending horizontally from semiconductor elements 6 are depressed as a whole, whereby the other end portion of each of flexible substrates 7 is bent and wirings 9 of first to fourth semiconductor packages 2 to 5 and mother substrate 1 are bonded together. As a result of the bending deformation of flexible substrates 7 by use of tool 16, tension 17 is generated in flexible substrates 7. Due to this tension 17, tensile stress 18 is generated in bonded portion 201 between flexible substrates 7 and in bonded portion 201 between mother substrate 1 and flexible substrate 7 as shown in FIG. 5D.

(5) Next, the pair of longitudinal members 21 is removed from between flexible substrates 7. As a result of the removal of longitudinal members 21, longitudinal members 21 no longer support flexible substrates 7 and, as shown in FIG. 5E, tension 17 generated in flexible substrates 7 decreases. As a result of this, tensile stress 18 generated in bonded portion 201 between flexible substrates 7 is reduced and it is possible to improve the reliability of bonded portion 201.

(6) Last, as shown in FIG. 5F, solder balls 11 are provided on a surface of mother substrate 1 opposite to the surface where first to fourth semiconductor packages 2 to 5 are disposed.

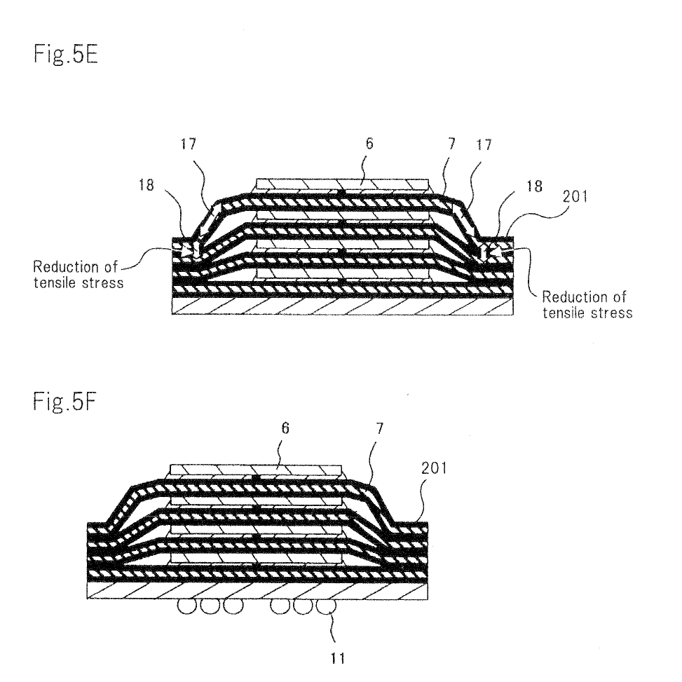

FIG. 7A is a diagram showing the stress distribution at a bounding interface between flexible substrate 7 positioned at the highest level and flexible substrate 7 positioned immediately thereunder in semiconductor packages fabricated on the basis of the method of manufacturing the semiconductor device described in the first embodiment. FIG. 7A shows, for comparison, also the stress distribution of a structure related to the present invention, which was fabricated by the method of manufacturing a semiconductor device not including the step of reducing the tension of flexible substrates 7. The abscissa of FIG. 7A indicates the distance in the direction of distance x from the interface end portion of bonded portion 201 shown in FIG. 7B which is zero (origin). The ordinate of FIG. 7A indicates the magnitude of the principal stress.

As shown in FIG. 7A, in the structure of the semiconductor packages of this embodiment, the tensile stress generated at the interface of bonded portion 201 decreases. Therefore, in this embodiment, it is possible to improve the reliability of bonded portions 201 of flexible substrates 7.

### Third and Fourth Embodiments

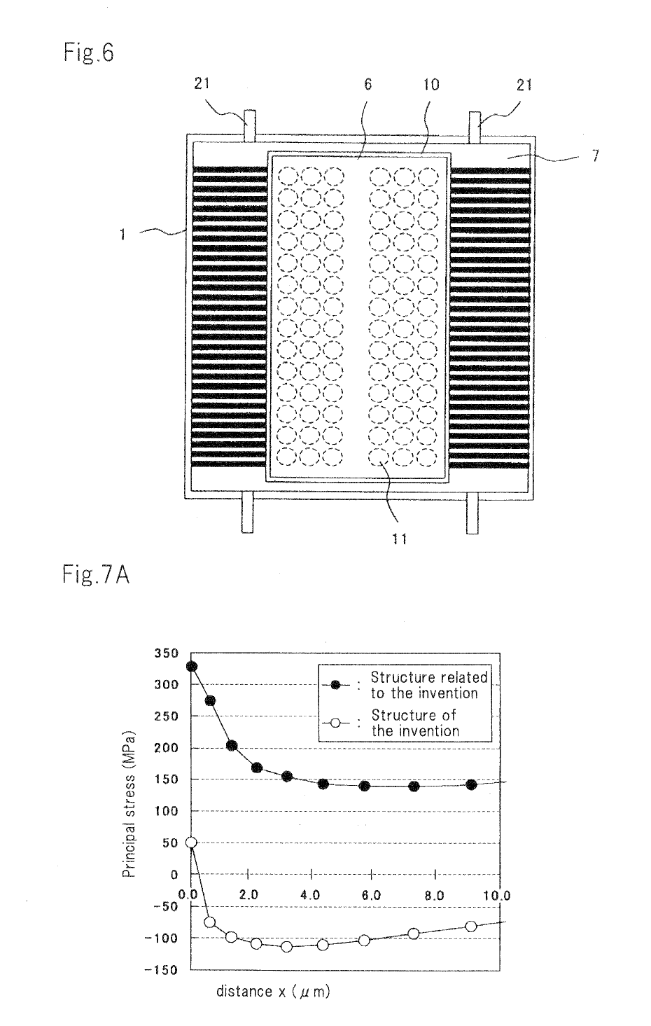

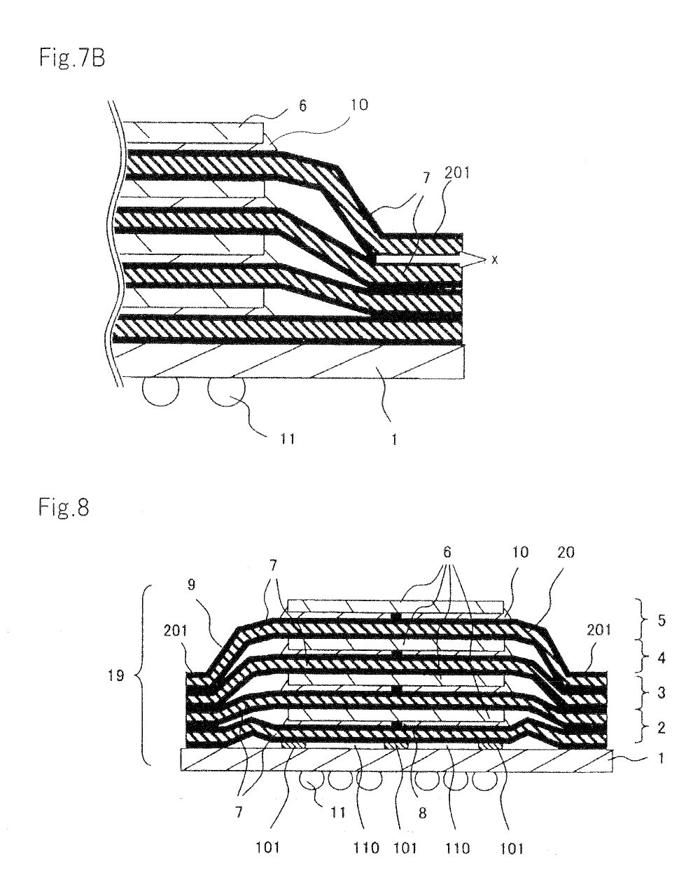

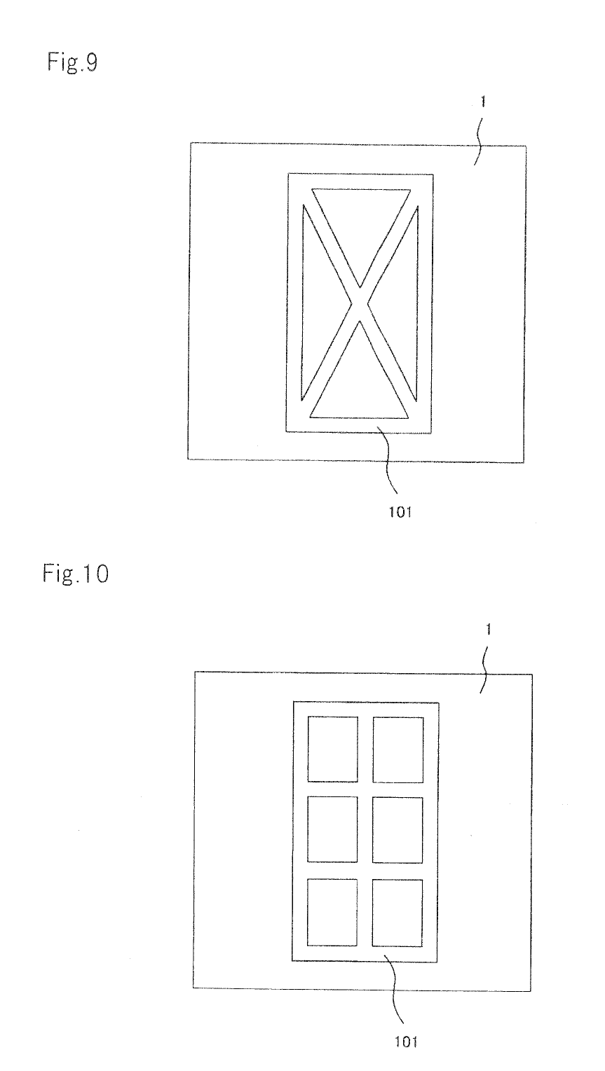

FIG. 8 shows a sectional view of the essential part of a semiconductor device of the third embodiment. FIG. 9 shows a plan view of a spacer of the semiconductor device of the third embodiment shown in FIG. 8 provided on mother substrate 1. FIG. 10 is a plan view showing a spacer of the semiconductor device of the fourth embodiment, which is a modification of the configuration shown in FIG. 9.

In this embodiment, resin members 101 as spacers are provided between mother substrate 1 and first semiconductor package 2. After the bonding of a plurality of flexible substrates 7 in bonded portions 201, semiconductor elements 6 of fourth semiconductor package 5 positioned at the highest level are depressed, whereby resin members 101 are deformed so that the height of resin members 101 decreases. A decrease in the height of resin members 1101 results in the relief of the stress generated in bonded portions 201 of flexible substrates 7.

Either thermoplastic resins or thermosetting resins may be used as the material for resin members 101. When thermoplastic resins are used, it is desirable to use polyimide resins, polypropylene resins, polyethylene resins and the like. Semiconductor elements 6 are deformed by being depressed, with resin members 101 softened in a heated atmosphere. When thermoplastic resins are used, it is desirable to use epoxy resins, phenol resins, melamine resins, urea resins, unsaturated polyester resins, alkyd resins, polyurethane, thermosetting polyimide and the like. Semiconductor elements 6 are deformed by being depressed at temperatures below the setting temperatures, and the thermosetting resin is thereafter caused to set by being heated.

For the shape of resin member 101, as shown in FIGS. 9 and 10, it is preferred that resin member 101 have a shape partly covering the space between mother substrate 1 and semiconductor element 6 of first semiconductor package, and not covering the entire space. This is because it is necessary to leave gap 110 into which resin member 101 spreads when resin member 101 is depressed. Incidentally, the shape of resin member 101 is not limited to the shapes shown in FIGS. 9 and 10, but any shape can be adopted so long as the shape has gap 110. That is, it is preferred that resin member 101 be provided in a part of a region present between the front surface of mother substrate 1 and semiconductor element 6 of first semiconductor package 2.

### Fifth Embodiment

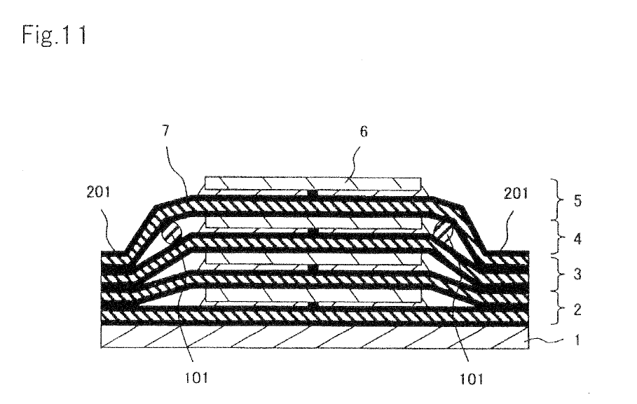

FIG. 11 is a sectional view showing the essential part of a semiconductor device of the fifth embodiment.

In this embodiment, as shown in FIG. 11, resin members 101 are disposed between flexible substrate 7 of third semiconductor package 4 and flexible substrate 7 of fourth semiconductor package 5. After the bonding of a plurality of flexible substrates 7 in bonded portions 201, the positions of flexible substrates 7 corresponding to the resin members are depressed, whereby resin members 101 are deformed so that the height of resin members 101 decreases. A decrease in the height of resin members 101 results in the relief of stress generated in bonded portions 201 of flexible substrates 7.

In addition, the installation position of resin members 101 is not limited to between flexible substrate 7 of third semiconductor package 4 and flexible substrate 7 of fourth semiconductor package 5. Resin members may be provided in any position between two semiconductor packages which are adjacent to each other in semiconductor packages 2 to 4. That is, it is necessary only that resin members 101 be provided in a part of a region between two semiconductor packages which are adjacent to each other.

It is apparent that the present invention is not limited to the above embodiments, but may be modified and changed without departing from the scope and spirit of the invention.

What is claimed is:

1. A semiconductor device comprising:
a plurality of semiconductor packages each having a semiconductor element and a flexible substrate in which the semiconductor element is provided with an overlap and is electrically connected, an end portion of the flexible substrate that extends from side surfaces of the semiconductor element, and that has wirings on both surfaces; and
a mother substrate on a front surface of which the plurality of semiconductor packages are stacked,
wherein the semiconductor device includes a stacked semiconductor package in which the end portions of the plurality of flexible substrates have bonded portions which are bonded together by the wirings, and the plurality of semiconductor packages are electrically connected to the mother substrate via the bonded portions,
wherein, in at least a part of a portion where regions of the plurality of flexible substrates are present between the side surfaces of each of the semiconductor elements and the bonded portions of the flexible substrates, and in which the plurality of flexible substrates extend from the side surfaces of each of the semiconductor elements, the plurality of flexible substrates have a curved portion and
wherein the shape of the curved portion of at least one of the flexible substrates is different from the shape of a curved portion of another flexible substrate adjacent to the flexible substrate.

2. The semiconductor device according to claim 1, wherein
the curvature of the curved portion of the flexible substrate in a portion where the curved portion intersects a normal line of the front surface of the mother substrate is different, in at least a part of a region, from the curvature of a curved portion of another flexible substrate adjacent to the flexible substrate in a position where the curved portion intersects the normal line.

3 The semiconductor device according to claim 1, wherein
the curved portion of the flexible substrate in at least the part of the region is such that, in a section formed by a direction which heads away from the semiconductor elements to the bonded portions and formed by a normal line direction of the front surface of the mother substrate, the inclination of the front surface of the curved portion is positive with respect to a direction which is parallel to the front surface of the mother substrate and which heads from the semiconductor elements to the bonded portions.

4. The semiconductor device according to claim 1, wherein
the curved portion of the flexible substrate in at least a part of the region is such that, in a section formed by a direction which heads away from the semiconductor elements to the bonded portions and formed by a normal line direction on the front surface of the mother substrate, the front surface of the curved portion has an apex with respect to the direction which is parallel to the front surface of the mother substrate.

5. The semiconductor device according to claim 1, further comprising:
a resin member which reduces stress generated in the bonded portion of the flexible substrate, and which is provided between the semiconductor package and the mother substrate or between two adjacent semiconductor packages.

6. The semiconductor device according to claim 5, wherein
the resin member is provided in a part of a region between the semiconductor package and the mother substrate or in a part of a region between two adjacent semiconductor packages.

7. A semiconductor device, comprising:
a plurality of semiconductor packages each having a plate-like semiconductor element and a flexible substrate in which the semiconductor element is provided with an overlap and is electrically connected, an end portion of the flexible substrate that extends from side surfaces of the semiconductor element, and that has wirings on both surfaces; and
a mother substrate on a front surface of which the plurality of semiconductor packages are stacked,
wherein the semiconductor device includes a stacked semiconductor package in which the end portions of the plurality of flexible substrates have bonded portions which are bonded together by the wirings, and the plurality of semiconductor packages are electrically connected to the mother substrate via the bonded portions, and
wherein both end portions of at least one of the flexible substrates are bonded to the bonded portions, with a region between the side surfaces of the semiconductor element and the bonded portions kept in a loose condition.

8. The semiconductor device according to claim 7, wherein
at least a part of a region present between the side surfaces of the semiconductor element and the bonded portions in both end portions of the semiconductor package, which is disposed adjacent to the front surface of the mother substrate, has a gap between the flexible substrate and the front surface of the mother substrate.

9. A method of manufacturing a semiconductor device comprising: a plurality of semiconductor packages each having a semiconductor element and a flexible substrate in which the semiconductor element is provided with an overlap and is electrically connected, an end portion of the flexible substrate that extends from side surfaces of the semiconductor element, and that has wirings on both surfaces; and a mother substrate on a front surface of which the plurality of semiconductor packages are stacked, and the semiconductor device that includes a stacked semiconductor package in which the end portions of the plurality of flexible substrates have bonded portions which are bonded together by the wirings, and the plurality of semiconductor packages are electrically connected to the mother substrate via the bonded portions, the method having:
a first step of disposing the plurality of semiconductor packages and a spacer for spacing the semiconductor element or the flexible substrate from the mother substrate by stacking them on the front surface of the mother substrate;
a second step of forming the bonded portions by depressing the end portions of the plurality of flexible substrates;
a third step of removing the spacer from the stacked semiconductor package; and
a fourth step of bringing the plurality of semiconductor packages into intimate contact with the mother substrate by depressing the semiconductor elements of the semiconductor packages which are stacked on the mother substrate.

10. The method of manufacturing a semiconductor device according to claim 9, wherein
in the first step the spacer is provided by being brought into contact with the mother substrate.

11. The method of manufacturing a semiconductor device according to claim 9, wherein
in the first step the spacer is provided between the flexible substrate and the flexible substrate.

12. The method of manufacturing a semiconductor device according to claim 9, wherein
in the first step the spacer is disposed in both end portions of the flexible substrate.

13. The method of manufacturing a semiconductor device according to claim 9, wherein
in the second step bonding is performed by depressing the bonded portions of the flexible substrates by use of an ultrasonic tool.

14. The method of manufacturing a semiconductor device according to claim 9, wherein
in the second step bonding is performed by depressing the bonded portions of the flexible substrates by use of a heating tool.

15. A method of manufacturing a semiconductor device comprising: a plurality of semiconductor packages each having a semiconductor element and a flexible substrate in which the semiconductor element is provided with an overlap and is electrically connected, an end portion of the flexible substrate that extends from side surfaces of each of the semiconductor elements, and that has wirings on both surfaces; and a mother substrate on a front surface of which the plurality of semiconductor packages are stacked, and the semiconductor device that includes a stacked semiconductor package in which the end portions of the plurality of flexible substrates have bonded portions which are bonded together by the wirings, and the plurality of semiconductor packages are electrically connected to the mother substrate via the bonded portions, the method having:
a first step of disposing the plurality of semiconductor packages and a spacer for spacing the semiconductor element or the flexible substrate from the mother substrate by stacking them on the front surface of the mother substrate;
a second step of forming the bonded portions by depressing the end portions of the plurality of flexible substrates; and
a third step of deforming the spacer by depressing the semiconductor elements or flexible substrates of the semiconductor packages which are stacked on the mother substrate.

16. The method of manufacturing a semiconductor device according to claim 15, wherein
in the third step the spacer is formed of a resin material.

17. The method of manufacturing a semiconductor device according to claim 15, wherein
in the third step the spacer is provided by being brought into contact with the mother substrate.

18. The method of manufacturing a semiconductor device according to claim 15, wherein
in the third step the spacer is provided between the flexible substrate and the flexible substrate.

19. The method of manufacturing a semiconductor device according to claim 15, wherein
in the third step the space is formed to have a shape having a gap which widens when the spacer is deformed.
